(19) United States
(12) Patent Application Publication
(10) Pub. No.: US 2026/0182444 A1
(43) Pub. Date: Jun. 25, 2026

(54) SEMICONDUCTOR PACKAGE AND METHOD OF MANUFACTURING THE SAME

(71) Applicant: Samsung Electronics Co., Ltd., Suwon-si (KR)

(72) Inventor: Jesung Kim, Suwon-si (KR)

(21) Appl. No.: 19/416,323

(22) Filed: Dec. 11, 2025

(30) Foreign Application Priority Data
Dec. 23, 2024 (KR) 10-2024-0194678

(51) Int. Cl. H10W 74/10; B23K 101/40

(52) U.S. Cl. CPC H10W 74/141; H10P 54/30; H10P 58/20; H10W 72/234; H10W 74/012; H10W 74/137; H10W 74/15; H10W 90/724; B23K 2101/40; H10W 90/7295

(57) ABSTRACT

A semiconductor package includes a substrate, a semiconductor chip mounted on the substrate, and including a stopper structure, chip connection bumps arranged between the substrate and the semiconductor chip, and an underfill material layer surrounding side surfaces of the chip connection bumps, wherein the stopper structure has a shape protruding from or recessed into a side surface of the semiconductor chip along an inclined surface with respect to a vertical direction.

### CROSS-REFERENCE TO RELATED APPLICATION

This application is based on and claims priority under 35 U.S.C. § 119 to Korean Patent Application No. 10-2024-0194678, filed on Dec. 23, 2024, in the Korean Intellectual Property office, the disclosure of which is incorporated by reference herein in its entirety.

### BACKGROUND

A laser manufacturing process is referred to as a process of manufacturing a shape, physical property, or the like, of a workpiece surface by irradiating a laser beam on the workpiece surface. The laser manufacturing process includes, for example, a patterning process of forming a pattern on a surface of a workpiece, a process of transforming the physical properties of the workpiece like a wafer annealing process, a molding process of changing the shape of the workpiece by applying heat melting, a cutting process of cutting the workpiece into units by applying the heat melting, etc.

In a conventional wafer dicing process using a laser beam, the workpiece is cut by irradiating a laser beam of a wavelength band with a high absorption rate and by heat melting the workpiece. When a wafer is cut by using a melting process, there is an issue that not only the cutting region but the surrounding region is melted, and accordingly, some of semiconductor devices formed on a wafer are damaged.

To solve this issue, a stealth dicing process is used to induce internal cracks by focusing a laser beam into a wafer.

In addition, as a way to fill the gap between a semiconductor chip and a mounting substrate, an underfill process using an underfill material has recently been used. The underfill material protects chip connection bumps arranged between the semiconductor chip and the mounting substrate from the external environment, and also mitigates stress caused by the difference in the thermal expansion coefficients between the semiconductor chip and the mounting substrate.

### SUMMARY

The present disclosure provides a method of manufacturing a semiconductor package having improved reliability and a method of manufacturing the semiconductor package.

In addition, the issues to be solved by the technical idea of the present disclosure are not limited to those mentioned above, and other issues may be clearly understood by those of ordinary skill in the art from the following descriptions.

According to an aspect of the present disclosure, a semiconductor package includes a substrate, a semiconductor chip mounted on the substrate, and including a stopper structure, chip connection bumps arranged between the substrate and the semiconductor chip, and an underfill material layer surrounding side surfaces of the chip connection bumps, wherein the stopper structure has a shape protruding from or recessed into a side surface of the semiconductor chip along an inclined surface with respect to a vertical direction.

According to according to another aspect of the present disclosure, a method of manufacturing a semiconductor package includes providing a wafer including a plurality of device forming regions and a scribe lane region configured to define the plurality of device forming regions, forming a plurality of semiconductor devices respectively in the plurality of device forming regions of the wafer, forming a plurality of internal breakages on the wafer by irradiating a first laser beam and a second laser beam along the scribe lane region, forming a stopper structure on side surfaces of the plurality of semiconductor devices by separating the plurality of semiconductor devices from each other along the plurality of internal breakages, and packaging each of the separated plurality of semiconductor devices, wherein the stopper structure has a shape protruding from or recessed into side surfaces of the semiconductor device along an oblique surface in a vertical direction.

According to another aspect of the present disclosure, a semiconductor package includes a substrate, a semiconductor chip mounted on the substrate, and including a stopper structure on side surfaces of the semiconductor chip, chip connection bumps arranged between the substrate and the semiconductor chip, a dam structure configured to surround the semiconductor chip on the substrate, and an underfill material layer surrounding side surfaces of the chip connection bumps, wherein the stopper structure has a shape protruding toward an outer side of the semiconductor chip or recessed into an inner side of the semiconductor chip along a first surface of a first oblique line direction inclined with respect to a vertical direction and a second surface of a second oblique line direction that is different from the first oblique line direction, and wherein an edge of the underfill material layer is in contact with the dam structure, and an upper end of the underfill material layer is in contact with the stopper structure.

### BRIEF DESCRIPTION OF THE DRAWINGS

Implementations will be more clearly understood from the following detailed description taken in conjunction with the accompanying drawings in which:

FIG. 1 is a schematic cross-sectional view of a semiconductor package according to an implementation;

FIG. 2 is an enlarged cross-sectional view of region I in FIG. 1;

FIGS. 3A through 3D are schematic cross-sectional views of a semiconductor chip including a stopper structure, according to various implementations;

FIG. 4A is a schematic plan view of a semiconductor package according to an implementation;

FIG. 4B is an example cross-sectional view of the semiconductor package taken along line III-III′ in FIG. 4A;

FIG. 5 is a schematic flowchart of a method of manufacturing a semiconductor chip, according to an implementation;

FIGS. 6 through 11 are schematic diagrams describing a method of manufacturing a semiconductor package, according to implementations;

FIGS. 12A and 12B are example enlarged diagrams of region II in FIG. 7; and

FIG. 13 is a block diagram of a wafer processing apparatus used in a method of manufacturing a semiconductor package, according to an implementation.

### DETAILED DESCRIPTION

Hereinafter, implementations of the present disclosure are described in detail with reference to the accompanying drawings. Identical reference numerals are used for the same constituent elements in the drawings, and duplicate descriptions thereof are omitted.

In the implementations below, the terms “first,” “second,” or the like, may not be used with limited meaning, but may be used to distinguish one component from another. As used herein, the singular forms “a,” “an” and “the” are intended to include the plural forms as well, unless the context clearly indicates otherwise.

In the present disclosure, a vertical direction may be defined as a Z direction, and a horizontal direction may be defined as a direction perpendicular to the Z direction. A vertical level may be referred to as a height level in a vertical direction (Z direction). A horizontal width of a component may be referred to as a length of the component in the horizontal direction, and a vertical width of a component may be referred to as a length of the component in the vertical direction.

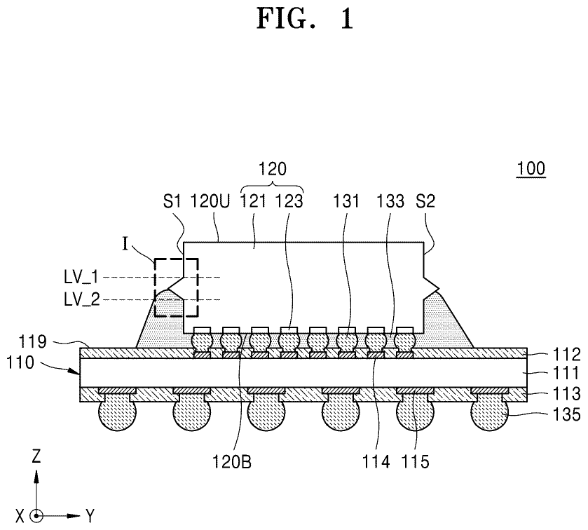

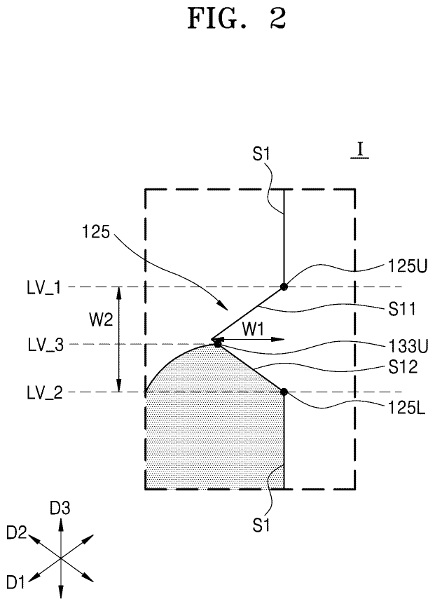

FIG. 1 is a schematic cross-sectional view of a semiconductor package 100 according to an implementation, and FIG. 2 is an enlarged cross-sectional view of region I in FIG. 1.

Referring to FIG. 1, the semiconductor package 100 may include a mounting substrate 110, a semiconductor chip 120 including a stopper structure 125, and an underfill material layer 133.

The mounting substrate 110 may have generally a flat plate shape or a panel shape. The mounting substrate 110 may include an upper surface 119 and a lower surface opposite thereto, and each of the upper surface 119 and the lower surface may include flat surfaces. The upper surface 119 of the mounting substrate 110 may be in parallel with a first horizontal direction (X direction) and a second horizontal direction (Y direction). The mounting substrate 110 may include a printed circuit board (PCB) or an interposer substrate. In the present disclosure, the mounting substrate 110 may also simply be referred to as a substrate.

The mounting substrate 110 may include a base layer 111, upper connection pads 114, lower connection pads 115, an upper passivation layer 112, and a lower passivation layer 113.

The base layer 111 may include at least one material of a phenol resin, an epoxy resin, and polyimide. For example, the base layer 111 may include at least one material selected from polyimide, flame retardant 4 (FR-4), tetrafunctional epoxy, polyphenylene ether, epoxy/polyphenylene oxide, bismaleimide triazine (BT), thermount, cyanate ester, and liquid crystal polymer.

The upper connection pads 114 may be provided on an upper surface of the base layer 111, and the lower connection pads 115 may be arranged under a lower surface of the base layer 111. Inside the base layer 111, an internal wiring configured to electrically connect the upper connection pads 114 to the lower connection pads 115 may be provided. The upper connection pads 114 and the lower connection pads 115 may include a metal, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), and ruthenium (Ru), or an alloy thereof.

The upper passivation layer 112 may be arranged on the upper surface of the base layer 111, and the lower passivation layer 113 may be arranged under the lower surface of the base layer 111. The upper passivation layer 112 may be formed to cover the upper surface of the base layer 111, and may cover a portion of each of the upper connection pads 114. The upper passivation layer 112 may include upper openings for exposing the upper connection pads 114. The lower passivation layer 113 may be formed to cover the lower surface of the base layer 111, and may cover a portion of each of the lower connection pads 115. The lower passivation layer 113 may include lower openings for exposing the lower connection pads 115. The upper passivation layer 112 and the lower passivation layer 113 may include, for example, solder resist.

Connection terminals 135 may be respectively attached to the lower connection pads 115 of the mounting substrate 110. The connection terminals 135 may be respectively connected to the lower connection pads 115 via the lower openings of the lower passivation layer 113. The connection terminals 135 may be configured to electrically and physically connect the mounting substrate 110 to an external device on which the mounting substrate 110 is mounted. The connection terminals 135 may be formed of, for example, solder balls or solder bumps.

The semiconductor chip 120 may be mounted on the mounting substrate 110. The semiconductor chip 120 may include a semiconductor substrate 121 and a chip pad 123. The semiconductor substrate 121 may include an upper surface 120U and a lower surface 120B opposite to each other. The lower surface 120B of the semiconductor substrate 121 may include an active surface of the semiconductor substrate 121, and the upper surface 120U of the semiconductor substrate 121 may include an inactive surface of the semiconductor substrate 121. The semiconductor substrate 121 may be formed of a semiconductor wafer. The semiconductor substrate 121 may include, for example, silicon (Si). Alternatively, the semiconductor substrate 121 may include a semiconductor element such as germanium (Ge), or a compound semiconductor such as silicon carbide (SiC), gallium arsenide (GaAs), indium arsenide (InAs), and indium phosphide (InP). The semiconductor substrate 121 may include a conductive region, for example, a well doped with an impurity, or a structure doped with an impurity. A semiconductor device layer including individual elements may be provided on the active surface of the semiconductor substrate 121. The individual elements may include, for example, a transistor. The individual elements may include micro-electronic devices, such as a metal-oxide-semiconductor field effect transistor (MOSFET), a system large scale integration (LSI), and a CMOS imaging sensor (CIS), a micro-electro-mechanical system (MEMS), active elements, and passive elements. The chip pad 123 may be provided under the lower surface 120B of the semiconductor chip 120, and may be electrically connected to individual elements of the semiconductor device layer.

The semiconductor chip 120 may be mounted on the mounting substrate 110 in a flip chip manner. The semiconductor chip 120 may be electrically and physically connected to the mounting substrate 110 via chip connection bumps 131. The chip connection bumps 131 may be respectively attached to the chip pads 123 of the semiconductor chip 120 and the upper connection pads 114 of the mounting substrate 110. The chip connection bumps 131 may include solder bumps. In the semiconductor package 100, an electronic component such as a manual component may be mounted on another region of the mounting substrate 110 outside the semiconductor chip 120.

In some implementations, the semiconductor chip 120 may include a memory chip. The memory chip may include a volatile memory semiconductor chip, such as dynamic random access memory (RAM) (DRAM) and static RAM (SRAM), or a non-volatile memory chip, such as phase-change RAM (PRAM), magneto-resistive RAM (MRAM), ferroelectric RAM (FeRAM), and resistive RAM (RRAM). In some implementations, the semiconductor chip 120 may include a logic chip. The logic chip may include a central processing unit (CPU) chip, a graphics processing unit (GPU) chip, an application processor (AP) chip, or an application specific integrated circuit (ASIC) chip.

The underfill material layer 133 may be arranged between the semiconductor chip 120 and the mounting substrate 110. The underfill material layer 133 may fill a gap between the semiconductor chip 120 and the mounting substrate 110, and surround the chip connection bumps 131. A portion of the underfill material layer 133 may extend outward from side surfaces of the semiconductor chip 120. A portion of the underfill material layer 133 may be in contact with a lower portion of each of the side surfaces of the semiconductor chip 120. The underfill material layer 133 may surround at least portions of the side surfaces of the semiconductor chip 120. The underfill material layer 133 may include an epoxy resin. For example, the underfill material layer 133 may be formed by using a capillary under-fill process. In some implementations, the under-fill material layer 133 may also include a non-conductive film.

The semiconductor chip 120 included in the semiconductor package 100 according to an implementation may include the stopper structure 125. The stopper structure 125 may be on first and second side surfaces S1 and S2 of the semiconductor chip 120. In an implementation, the semiconductor chip 120 may include four side surfaces on a flat surface, and the stopper structure 125 may be on the four side surfaces of the semiconductor chip 120. The stopper structure 125 may be on the side surfaces of the semiconductor substrate 121 of the semiconductor chip 120.

The stopper structure 125 may have a shape protruding from or recessed into the side surfaces of the semiconductor chip 120 along a surface inclined in a vertical direction (Z direction). It may be understood that the side surface of the semiconductor chip 120 extends generally in the vertical direction (Z direction), and one region of the side surface of the semiconductor chip 120, where the stopper structure 125 is arranged, has inclinations that protrude and/or are recessed in the horizontal direction.

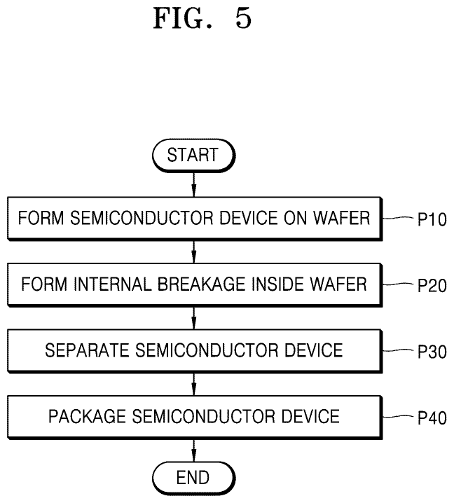

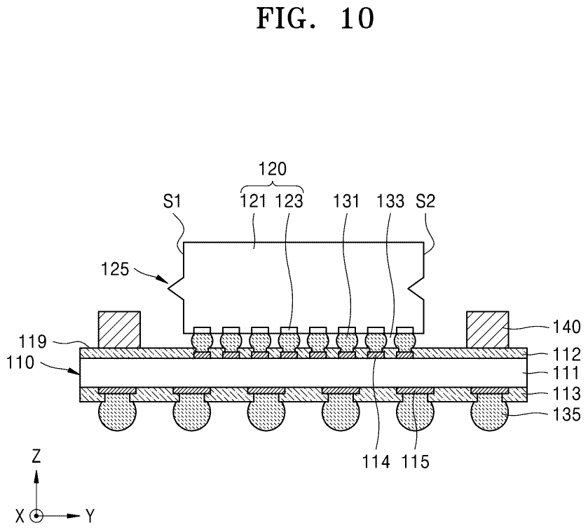

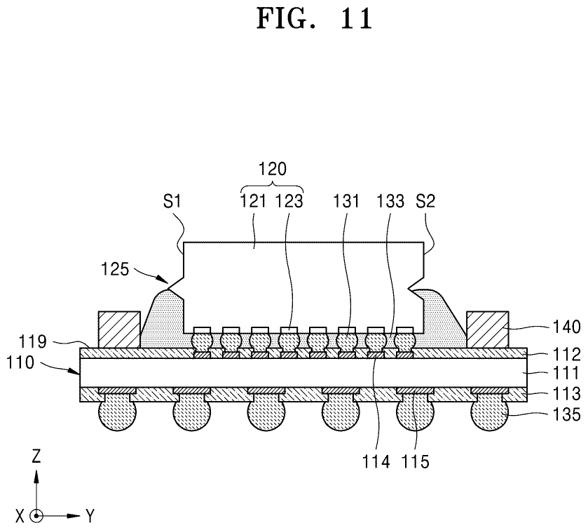

The stopper structure 125 may be formed together in the wafer dicing process in which a wafer, on which a plurality of semiconductor chips 120 are formed, is separated into each of the plurality of semiconductor chips 120. Detailed descriptions thereof are given below with reference to FIGS. 5 through 13B.

The semiconductor chip 120 may include the first side surface S1 and the second side surface S2 extending generally in the vertical direction (Z direction). The stopper structure 125 may be in one region of the first side surface S1 and one region of the second side surface S2. Hereinafter, descriptions are given mainly on the stopper structure 125 on the first side surface S1 of the semiconductor chip 120, and the descriptions of the stopper structure 125 on the first side surface S1 may be substantially equally applicable to the stopper structure 125 on the second side surface S2 and/or other side surfaces of the semiconductor chip 120. In the implementation, the stopper structure 125 may be formed in a ring shape surrounding the side surfaces of the semiconductor chip 120.

Referring to FIGS. 1 and 2, the stopper structure 125 may be at the center portions of the first and second side surfaces S1 and S2. In the implementation, a vertical level LV_1 of an uppermost end 125U of the stopper structure 125 may be lower than a vertical level of the upper surface 120U of the semiconductor chip 120, and a vertical level LV_2 of a lowermost end 125L of the stopper structure 125 may be higher than a vertical level of the lower surface 120B of the semiconductor chip 120. Accordingly, the upper portion and lower portion of the side surface of the semiconductor chip 120 may extend in the vertical direction (Z direction), and the stopper structure 125 may be between portions of the side surface (upper and lower portions of the side surface) of the semiconductor chip 120 extending in the vertical direction (Z direction).

Referring to FIG. 2, the stopper structure 125 on the first side surface S1 of the semiconductor chip 120 may include a first surface S11 and a second surface S12. The first surface S11 and the second surface S12 may include inclined surfaces with respect to the vertical direction (Z direction) and a vertical direction (D3 direction). The first surface S11 may extend in a first oblique line direction D1, and the second surface S12 may extend in a second oblique line direction D2. The first oblique line direction D1 may include a left-down direction or a right-up direction on a cross-section as illustrated in FIG. 2. The second oblique line direction D2 may include a right-down direction or a left-up direction on a cross-section as illustrated in FIG. 2. Referring to FIG. 2, the stopper structure 125 may include the first surface S11 and the second surface S12 forming a shape protruding outward from the semiconductor chip 120, on the first side surface S1 extending in the vertical direction (Z direction).

In the implementation, the first surface S11 and the second surface S12 may be connected to each other, and accordingly, the stopper structure 125 may protrude from and/or be recessed into the side surface of the semiconductor chip 120. In an implementation, at least one of the first surface S11 and the second surface S12 included in the stopper structure 125 may be provided in plural. In an implementation, a horizontal width W1 of the stopper structure 125 may be in a range of from about 5 μm to about 30 μm, and a vertical width W2 of the stopper structure 125 may be in a range of from about 80 μm to about 100 μm.

The semiconductor chip 120 included in the semiconductor package 100 according to various implementations may include the stopper structure 125. The stopper structure 125 may be arranged on the side surfaces of the semiconductor chip 120 so that in a process of forming the underfill material layer 133 by doping an underfill material thereon, the underfill material is prevented from overflowing along the side surfaces of the semiconductor chip 120 and in the direction of the upper surface 120U.

Referring to FIGS. 1 and 2, in the implementations, a vertical level LV_3 of an uppermost end 133U of the underfill material layer 133 may be lower than the vertical level LV_1 of the uppermost end 125U of the stopper structure 125. However, the implementation is not limited thereto. For example, unlike as illustrated in FIG. 2, the vertical level LV_3 of the uppermost end 133U of the underfill material layer 133 may be equal to or greater than the vertical level LV_1 of the uppermost end 125U of the stopper structure 125. In other words, the underfill material layer 133 may cover the stopper structure 125. Even in this case, the stopper structure 125 may physically reduce the speed and amount of the underfill material rising along the side surfaces of the semiconductor chip 120.

According to various implementations, the semiconductor chip 120 may have a polygonal (for example, rectangular) shape on a flat surface, and the stopper structures 125 may be on each side surface (for example, four side surfaces) of the semiconductor chip 120. Each of the stopper structures 125 on each side surface of the semiconductor chip 120 may have a protruding shape and/or a recessed shape.

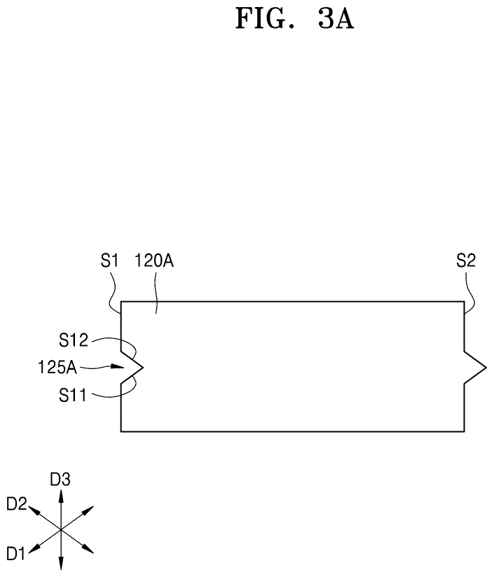

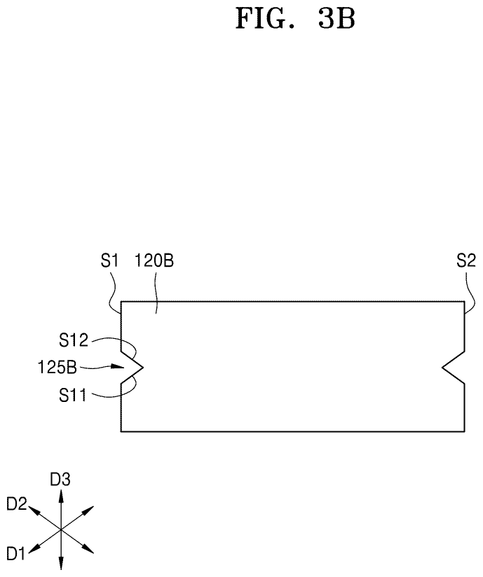

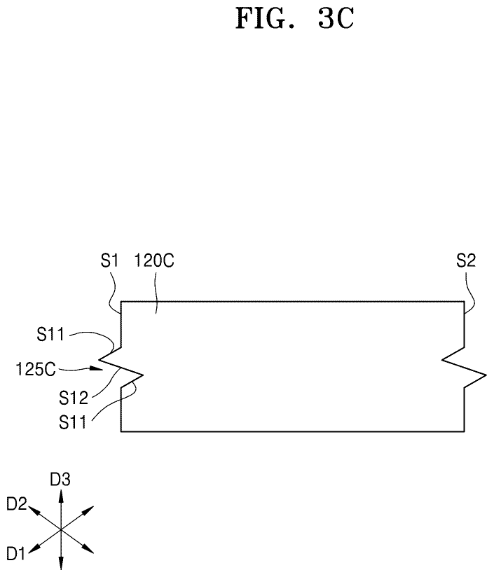

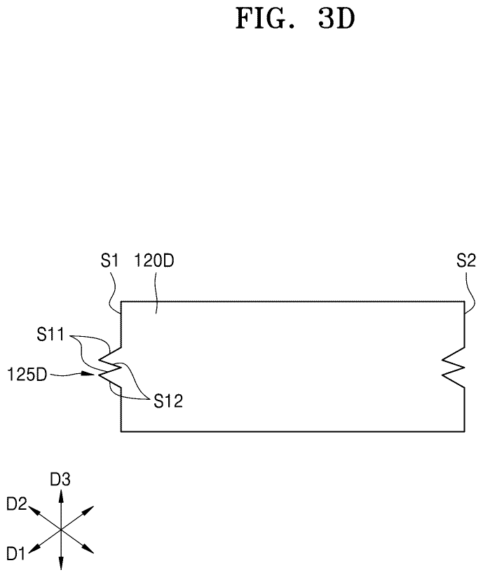

FIGS. 3A through 3D are schematic cross-sectional views of the semiconductor chip 120 including the stopper structure 125, according to various implementations.

Referring to FIG. 3A, a stopper structure 125A of a semiconductor chip 120A may include a shape recessed from a side surface of the semiconductor chip 120A. The stopper structure 125A may include the first surface S11 and the second surface S12 forming a shape recessed into the semiconductor chip 120, on the first side surface S1 extending in the vertical direction (Z direction). As described above, the first surface S11 and the second surface S12 may include surfaces extending in the first oblique line direction D1 and the second oblique line direction D2, which are inclined with respect to the vertical direction (Z direction), respectively. Referring to FIG. 3A, the stopper structure 125A included in the semiconductor chip 120A may have a shape that is recessed into the first side surface S1 of the semiconductor chip 120A and protrudes from the second side surface S2 of the semiconductor chip 120A.

Referring to FIG. 3B, a stopper structure 125B included in a semiconductor chip 120B may have recessed shapes on both the first side surface S1 and the second side surface S2 of the semiconductor chip 120B.

At least one of the first surface S11 and the second surface S12 included in stopper structures according to implementations may be provided in plural. A plurality of first surfaces S11 may be surfaces extending in the first oblique line direction D1 that is a left-down or right-up direction on each cross-section, and in an implementation, the plurality of first surfaces S11 may not be parallel with each other. Similarly, a plurality of second surfaces S12 may be surfaces extending in the second oblique line direction D2 that is a right-down or left-up direction on each cross-section, and in an implementation, the plurality of second surfaces S12 may not be parallel with each other.

FIG. 3C illustrates that a stopper structure 125C included in a semiconductor chip 120C includes two first surfaces S11 and one second surface S12. Accordingly, the stopper structure 125C may have both a shape protruding from the side surface and a shape recessed into the side surface in the vertical direction (Z direction). A first portion of the stopper structure 125C may protrude from the first side surface S1 in the vertical direction (Z direction), and a second portion may be recessed into the first side surface S1 in the vertical direction (Z direction). The first portion may be connected to the second portion, and on a cross-section, the stopper structure 125C may have generally a zigzag shape.

FIG. 3D illustrates that a stopper structure 125D included in a semiconductor chip 120D includes two first surfaces S11 and two second surfaces S22. Accordingly, the stopper structure 125D may have both a shape protruding from the side surface and a shape recessed into the side surface in the vertical direction (Z direction). The shape recessed into the first side surface S1 may be between two protruding shapes, and the shape protruding from the second side surface S2 may be between two recessed shapes. On a cross-section, the stopper structure 125D may have a “W” shape rotated by about 90 degrees.

FIGS. 3C and 3D illustrate that the first side surface S1 and the second side surface S2 have the stopper structures 125C having the same shape in cross-sections, but the implementation is not limited thereto. For example, the second side surface S2 may have the stopper structure 125C having a shape symmetrical in cross-section with the first side surface S1. In addition, the number of first surfaces and second surfaces of the stopper structures 125 and 125A through 125D on one side surface of the semiconductor chip 120 may be changed as necessary.

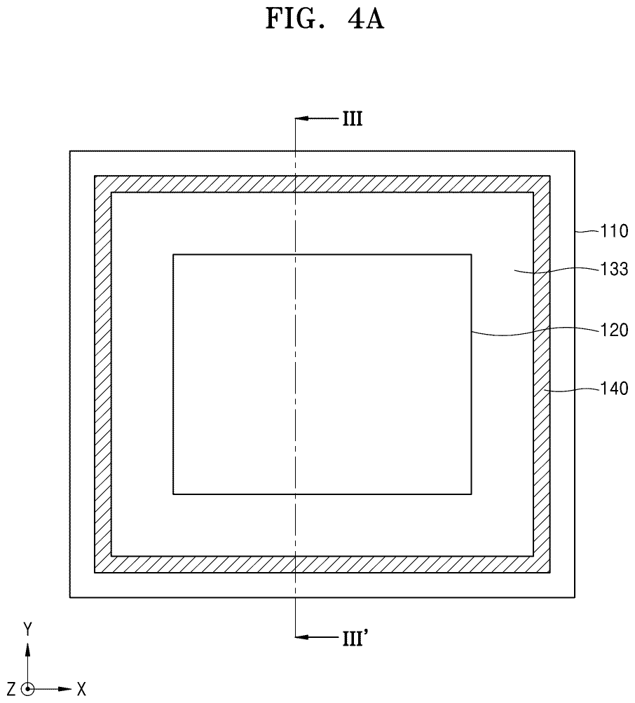

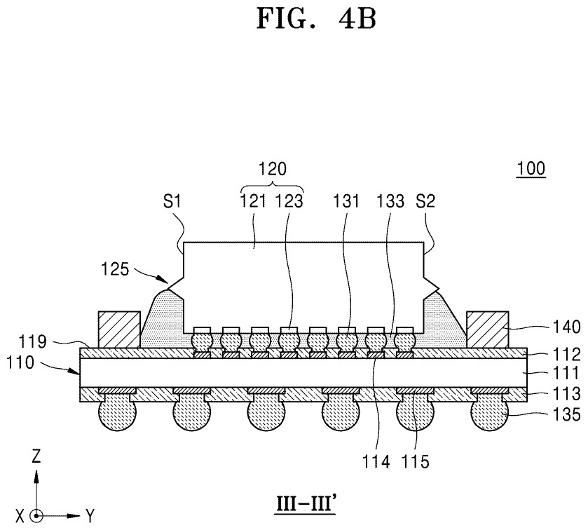

FIG. 4A is a schematic plan view of the semiconductor package 100 according to an implementation, and FIG. 4B is an example cross-sectional view of the semiconductor package 100 taken along line III-III′ in FIG. 4A.

Referring to FIGS. 4A and 4B, the semiconductor package 100 according to an implementation may further include a dam structure 140. The dam structure 140 may be arranged on a mounting substrate 110. The dam structure 140 may be attached onto the upper passivation layer 112 of the mounting substrate 110. The dam structure 140 may extend to surround the semiconductor chip 120 on the upper surface 119 of the mounting substrate 110. The dam structure 140 may have a ring shape surrounding the semiconductor chip 120. For example, the dam structure 140 may have a rectangular ring shape. For example, when the semiconductor chip 120 includes first through fourth sides, the dam structure 140 may extend along a virtual rectangular line surrounding the semiconductor chip 120.

The dam structure 140 may include an insulating material. For example, the dam structure 140 may include solder resist, epoxy resin, and/or polyimide. In some implementations, at least a portion of the dam structure 140 may include the same material as the upper passivation layer 112 of the mounting substrate 110. For example, a lower portion of the dam structure 140 may be in contact with the upper passivation layer 112, and may include the same material (for example, solder resist) as the upper passivation layer 112.

Referring to FIG. 4B, an edge of the underfill material layer 133 may be in contact with the dam structure 140, and an upper end of the underfill material layer 133 may be in contact with the stopper structure 125 of the semiconductor chip 120. An underfill material may be doped between the semiconductor chip 120 and the substrate 110 to form the underfill material layer 133, and the doped underfill material may flow outward from the semiconductor chip 120. The dam structure 140 may block the flow of the underfill material during the underfill process for forming the underfill material layer 133, control the final shape of the underfill material layer 133, and limit the formation region of the underfill material layer 133 to a region surrounded by the dam structure 140.

As the flow of the underfill material toward the outside of the semiconductor chip 120 is blocked by the dam structure 140, the underfill material may move in an upward direction of the semiconductor chip 120. As described above, the stopper structure 125 of the semiconductor chip 120 may physically interfere with the flow of the underfill material of the semiconductor chip 120, and prevent the underfill material from overflowing in the upward direction of the semiconductor chip 120.

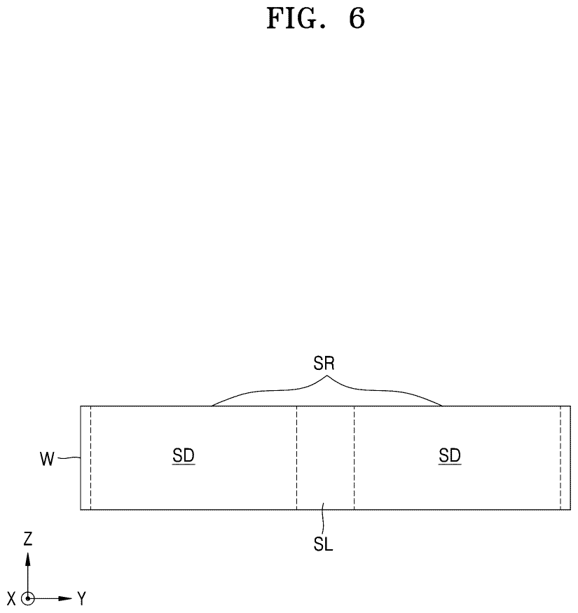

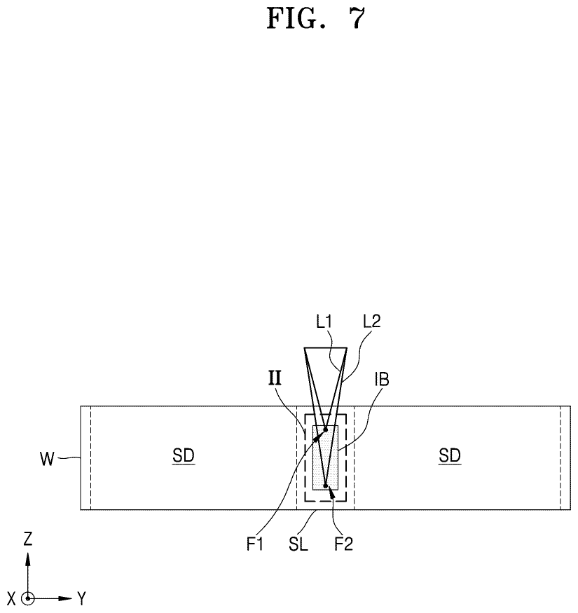

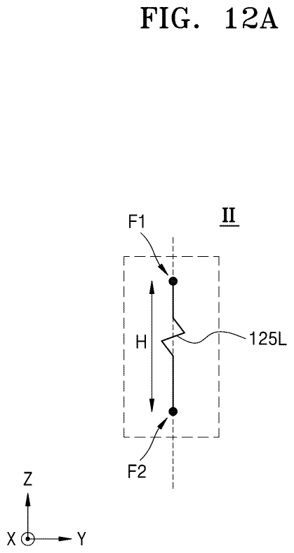

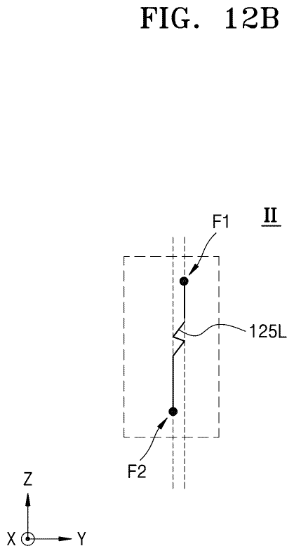

FIG. 5 is a schematic flowchart of a method of manufacturing the semiconductor package 100, according to an implementation. FIGS. 6 through 11 are schematic diagrams describing a method of manufacturing the semiconductor package 100, according to implementations. FIGS. 12A and 12B are example enlarged diagrams of region II in FIG. 7.

Referring to FIGS. 5 and 6, a plurality of semiconductor devices SD may be formed on a wafer W (P10). The wafer W may include a plurality of device forming regions SR in which the plurality of semiconductor devices SD are respectively formed, and a scribe lane region SL defining the plurality of device forming regions SR.

The wafer W may include, for example, silicon (Si). The wafer W may include a semiconductor element, such as germanium (Ge), or a compound semiconductor, such as silicon carbide (SiC), gallium arsenide (GaAs), indium arsenide (InAs), and indium phosphor (InP).

In some implementations, the wafer W may have a silicon on insulator (SOI) structure. The wafer W may include a buried oxide layer formed on the front surface of the wafer W. In some implementations, the wafer W may include a conductive region formed on the front surface of the wafer W, for example, an impurity-doped well. In some implementations, the wafer W may have various device isolation structures such as a shallow trench isolation (STI) structure which separates the impurity-doped wells apart from each other. Although not illustrated, a plurality of material layers may be formed on the front surface of the wafer W. At least one material layer may be formed on a rear surface of the wafer W.

The semiconductor device SD formed in the wafer W may be any one of a memory device and a non-memory device. In some implementations, the memory device may include, for example, a non-volatile memory device, such as flash memory, PRAM, MRAM, FeRAM, and RRAM. The flash memory may include, for example, a V-NAND flash memory. In some other implementations, the memory chip may include a volatile memory device, such as DRAM and SRAM. The memory device may also include a volatile memory device in which data is lost when power thereto is cut off. In an implementation, the non-memory device may include a logic chip, such as a CPU chip, a GPU chip, or an AP chip. In some implementations, the non-memory device may include a measurement device, a communication device, a digital signal processor (DSP), or a system-on-chip (SoC), etc.

A process of forming the semiconductor device SD may include an oxidation process for forming an oxide layer, a lithography process including spin coating, exposure and development, a thin layer deposition process, a dry or wet etching process, a metal wiring process, etc.

The oxidation process may include a process of forming a thin and uniform silicon oxide layer by chemically reacting oxygen or water vapor with the surface of the silicon substrate at a high temperature of about 800° C. to about 1,200° C. The oxidation process may include a dry oxidation process and a wet oxidation process. The dry oxidation process may form an oxide layer by reacting an Si substrate with oxygen gas, and the wet oxidation process may form an oxide layer by reacting oxygen with water vapor.

In some implementations, the SOI structure may be formed on a substrate by using an oxidation process. The substrate may also include a buried oxide layer. In some implementations, the substrate may have various device isolation structures such as the STI structure.

The lithography process may include a process of transferring a circuit pattern pre-formed on a lithography mask onto the substrate by using the exposure process. The lithography process may be performed in a sequence of a spin coating process, an exposure process, and a developing process.

The thin layer deposition process may include any one of, for example, an atomic layer deposition (ALD) process, a chemical vapor deposition (CVD) process, a plasma enhanced CVD (PECVD) process, a physical vapor deposition (PVD) process, a reactive pulsed laser deposition process, a molecular beam epitaxy process, and a direct current (DC) magnetron sputtering process.

The dry etching process may include any one of, for example, a reactive ion etching (RIE) process, a deep RIE (DRIE) process, an ion beam etching (IBE) process, and an argon (Ar) milling process. As another example, the dry etching process, which may be performed onto the wafer W, may include an atomic layer etching (ALE) process. In addition, the dry etching process, which may be performed onto the wafer W, may use, as an etchant gas, at least any one of Cl₂, HCl, CHF₃, CH₂F₂, CH₃F, H₂, BCL₃, SiCl₄, Br₂, HBr, NF₃, CF₄, C₂F₆, C₄F₈, SF₆, O₂, SO₂, and COS.

The metal wiring process may include a process of forming a conductive wiring (metal wire) for implementing a circuit pattern for an operation of the semiconductor device SD. By using the metal distribution process, a ground path, a power path, and a signal transfer path may be formed. The metal wire may include at least one metal element of Au, Pt, Ag, Cu, Al, Ti, Ta, and W.

In some implementations, in the semiconductor device SD forming process, a chemical mechanical polish (CMP) process and an etchback process, or an ion injection process, or the like may be performed.

Referring to FIGS. 5 and 7, an internal breakage IB may be formed (P20). The internal breakage IB may be formed in the scribe lane region SL. In some implementations, a pre-grinding process may be performed on a rear surface of the wafer W (that is, a surface opposite to the front surface of the wafer W on which the semiconductor device SD is formed) to reduce the thickness of the wafer W before forming an internal breakage IB in the wafer W.

In the implementation, the internal breakage IB inside the wafer W may be formed by irradiating a first laser beam L1 and a second laser beam L2 along the scribe lane region SL.

Referring to FIG. 7, in the process of manufacturing the semiconductor package 100 according to the implementation, the first laser beam L1 may be focused at a first focus location F1, and the second laser beam L2 may be focused at a second focus location F2. When the first laser beam L1 and the second laser beam L2 are irradiated, the first focus location F1 and the second focus location F2 may be apart from each other in the vertical direction (Z direction). The internal breakage IB due to the first laser beam L1 may be connected to the internal breakage IB due to the second laser beam L2 generally in the vertical direction (Z direction) to form a stopper line (refer to 125L in FIGS. 12A and 12B), and may separate the plurality of semiconductor devices SD from each other along the stopper line 125L.

In a conventional wafer dicing process, when a plurality of semiconductor devices are separated from each other, it may be possible to perform a dicing operation so that separation surfaces are aligned in the vertical direction (Z direction) without imbalance. The method of manufacturing the semiconductor package 100 according to various implementations may adjust intensity of the first laser beam L1 and the second laser beam L2, focus distances, locations, or the like, and may induce the imbalance of alignment of the internal breakage IB due to each of the first laser beam L1 and the second laser beam L2. The internal breakage IB due to the first laser beam L1 may be connected to the internal breakage IB due to the second laser beam L2 not in a line, but in a slanted shape in the vertical direction (Z direction). In an implementation, the intensity of the first laser beam L1 may be different from the intensity of the second laser beam L2.

Referring to FIG. 12A, in the implementation, the first focus location F1 of the first laser beam L1 may overlap the second focus F2 of the second laser beam L2 in the vertical direction (Z direction). By adjusting a distance H between the first focus location F1 of the first laser beam L1 and the second focus location F2 of the second laser beam L2, an alignment between the internal breakages IB of each of the first laser beam L1 and the second laser beam L2 may be misaligned. In an implementation, the distance between the first focal position F1 and the second focal position F2 may be increased up to a point where the alignment of the internal cracks IB due to each of the first laser beam L1 and the second laser beam L2 is misaligned.

Referring to FIG. 12B, in an implementation, the first focus location F1 of the first laser beam L1 may be apart (e.g., offset) from the second focus location F2 of the second laser beam L2 in the horizontal direction. In the implementation, the first focus location F1 of the first laser beam L1 may not overlap the second focus location F2 of the second laser beam L2 in the vertical direction (Z direction). In this manner, the alignment of the internal breakages IB due to each of the first laser beam L1 and the second laser beam L2 may be misaligned.

Referring to FIGS. 12A and 12B, due to alignment imbalance between the internal breakage IB due to the first laser beam L1 and the internal breakage IB due to the second laser beam L2, the stopper line 125L due to connection of the internal breakages IB may be formed in the scribe lane region SL. The stopper line 125L may be formed between the first focus location F1 and the second focus location F2. Thereafter, the plurality of semiconductor devices SD may be separated from each other along the stopper line 125L, and the stopper structure 125 may be formed on side surfaces of the plurality of semiconductor devices SD.

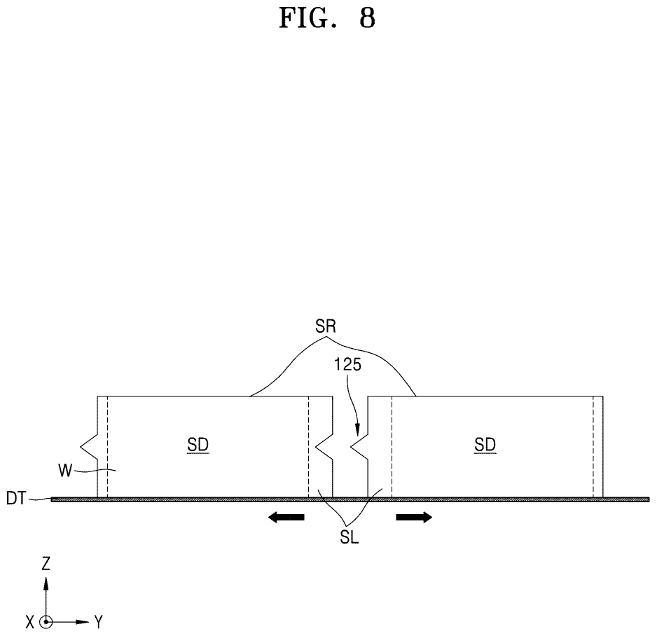

Referring to FIGS. 5 and 8 together, the semiconductor devices SD may be separated (P30).

After attaching the wafer W, where the internal breakage IB is formed, to a dicing tape DT, the dicing tape DT may be lengthened in the horizontal direction, and the semiconductor devices SD may be separated from each other along the internal breakage IB (along the stopper line 125L). In some implementations, before the dicing tape DT is attached onto the wafer W, a back grinding process of grinding a rear surface of the wafer W may be additionally performed.

As the semiconductor devices SD are separated from each other, the stopper structure 125L may be formed on the side surfaces of the semiconductor device SD. Referring to FIG. 8 together with FIGS. 12A and 12B, the semiconductor devices SD may be separated from each other with reference to the stopper line 125L formed by connecting the internal breakages IB to each other of the wafer W, and the stopper structure 125 having a shape protruding from or recessed into the side surfaces of the semiconductor devices SD along surfaces inclined in the vertical direction may be formed on the side surfaces of the semiconductor devices SD.

The semiconductor device SD including the stopper structure 125 formed on the side surface thereof may correspond to the semiconductor chips (120 and 120A through 120D) described above with reference to FIGS. 1, 2, and 3A through 3D, and descriptions of the semiconductor chips (120 and 120A through 120D) may be substantially equally applied to the semiconductor device SD including the stopper structure 125 formed therein. For example, the stopper structure 125 formed on the side surfaces of the semiconductor devices SD may include the first surface (refer to S11 in FIG. 2) and the second surface (refer to S12 in FIG. 2) inclined with respect to the vertical direction (Z direction). Each of the first surfaces S11 and the second surfaces S12 may be provided in plural (e.g., including a plurality of surfaces), and the first surfaces S11 and the second surfaces S12 may be alternately connected to each other.

Referring to FIG. 5, the separated semiconductor device SD may be packaged (P40). A packaging process may include a wire bonding process, a molding process, a marking process, a solder ball mounting process, etc.

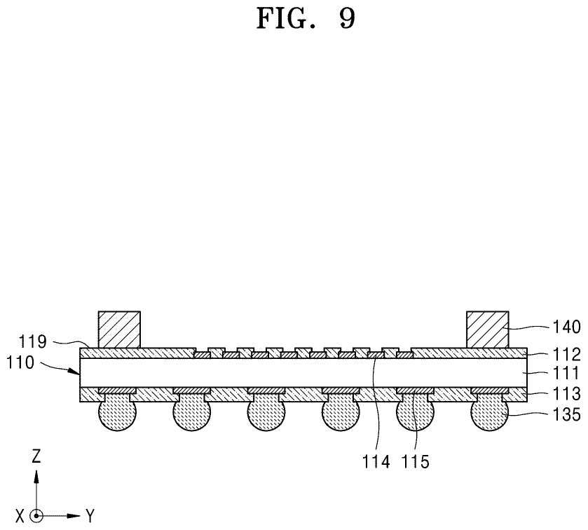

Referring to FIGS. 9 through 11, operation P40 of packaging the separated semiconductor device SD may firstly prepare the semiconductor substrate 110. The dam structure 140 may be arranged on the substrate 110, and may be substantially the same as the dam structure 140 described above with reference to FIGS. 4A and 4B. Thereafter, each of the plurality of semiconductor devices SD may be mounted on the substrate 110. Hereinafter, each of the plurality of semiconductor devices SD including the stopper structure 125 formed on the side surfaces thereof may be referred to as the semiconductor device SD. Thereafter, the underfill material layer 133 may be formed by doping the underfill material between the semiconductor chip 120 and the substrate 110. A flow of the underfill material in an outward direction of the semiconductor chip 120 may be controlled by the dam structure 140, and a flow of the underfill material in an upward direction of the semiconductor chip 120 may be controlled by the stopper structure 125.

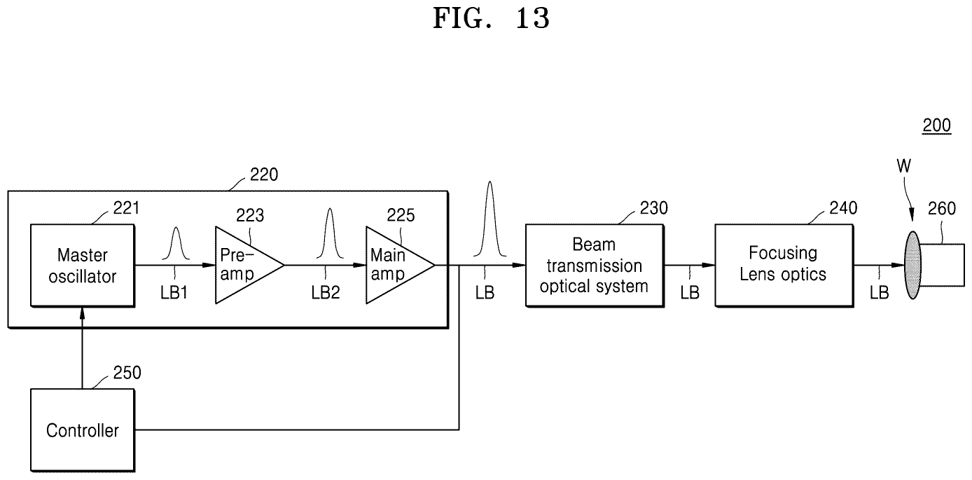

FIG. 13 is a block diagram of a wafer processing apparatus 200 used in a method of manufacturing the semiconductor package 100, according to an implementation.

Referring to FIG. 13, the wafer processing apparatus 200 may include a laser device 220, a beam transfer optical system 230, a focusing lens optics 240, and a wafer support 260.

The wafer processing apparatus 200 may perform a wafer dicing process. In some implementations, the wafer processing apparatus 200 may perform a stealth dicing process. The stealth dicing process may include a process of separating the wafer W including a semiconductor device formed thereon at a high precision and high speed. The stealth dicing may be technology of focusing a laser beam of a wavelength band capable of penetrating the wafer W (that is, a wavelength band having low absorption rate of the wafer W) at one point inside the wafer W via the surface of the wafer W.

In stealth dicing technology, the laser beam may be repeatedly irradiated as a pulse that lasts for a short time (for example, equal to or less than about 1 μs), and may be focused on a narrow region on the wafer W. In other words, the laser beam may, in the vicinity of the focus set inside the wafer W, have spatially (by focusing) and timely (by pulsing) a high peak power density of, for example, about 1×108 W/cm². A laser beam having a high peak power density may cause a non-linear absorption effect on the wafer W in the vicinity of the focal point, and accordingly, the laser beam having penetrated the surface of the wafer W may be absorbed a high absorption rate in the vicinity of the focal point inside the wafer W. Thus, the laser beam may perform phase-change on the portion that has absorbed the laser beam inside the wafer W, generate high-density defects (for example, electrical potential), and facilitate vertical cracks in the wafer W.

In some implementations, the laser device 220 may include a master oscillator and power amplifier (MOPA) laser device. The laser device 220 may include an optical fiber laser device. A master oscillator 221, a pre-amplifier 223, and a main amplifier 225, which are included in the laser device 220, may be coupled to each other via the optical fiber laser device. However, the implementation is not limited thereto, and the laser device 220 may include an MOPA laser device including a solid bulk laser device and a bulk amplifier, and may also include an MOPA laser device including a tunable external cavity diode laser device and a semiconductor optical amplifier.

In some implementations, the master oscillator 221 may include an optical fiber laser device doped with any one of yttrium (Yb), erbium (Er), thulium (Tm), and holmium (Ho). In some implementations, the master oscillator 221 may generate the first laser beam LB1 having a wavelength of about 0.8 μm to about 1.4 μm. In some implementations, the first laser beam LB1, the second laser beam LB2, and the laser beam LB may have a wavelength of about 1064 μm.

In some implementations, the master oscillator 221 may operate in a Q switching manner. The laser device 220 may generate the first laser beam LB1 at a pulse frequency of several hundred kHz. However, the implementation is not limited thereto, and in some other implementation, the master oscillator 221 may operate in a mode-locking manner.

The main oscillator 221may include a seed laser diode, an optical fiber including a gain medium, and a first mirror and a second mirror facing each other to resonate the first laser beam. The seed laser diode may include a diode generating a laser beam by using forward semiconductor junction as an active medium. When current is supplied to the seed laser diode, a beam may be irradiated when inversion occurs between density at a high energy level and density at a low energy level, at the semiconductor junction.

The beam emitted by the seed laser diode may be used as pumping energy for an optical fiber including the gain medium. When the seed laser diode is configured in plural, a pump-signal coupling device may be provided between a plurality of seed laser diodes and the optical fiber. The pump-signal coupling device may couple optical signals output by the plurality of seed laser diodes into one signal, and transmit the one signal to an optical fiber including the gain medium.

The beam spontaneously emitted or emitted by inducement by the gain medium of the optical fiber may be mostly weak in directionality. A first mirror and a second mirror may reflect again the beam emitted by the gain medium to generate resonance in which induced emittance of the gain medium is repeated. Some of the beams repeatedly emitted between the first and second mirrors may penetrate the second mirror and be output as the first laser beam LB1. The first laser beam LB1 may include a coherent beam.

The master oscillator 221 may further include an optical modulator for adjusting the intensity-time profile of the first laser beam LB1. The optical modulator may include an aperture capable of passing or closing the first laser beam LB1, and may adjust the intensity-time profile of the pulse of the first laser beam LB1 by adjusting the transmittance of the first laser beam LB1 penetrating the aperture.

The pre-amplifier 223 may include a first pump laser diode, and the main amplifier 225 may include a second pump laser diode. In some implementations, the first pump laser diode included in the pre-amplifier 223 may be provided in plural. In some implementations, the second pump laser diode included in the main amplifier 225 may be provided in plural.

The pre-amplifier 223 may amplify the first laser beam LB1 and output the second laser beam LB2. The second laser beam LB2 and the first laser beam LB1 may have the same wavelength. The main amplifier 225 may amplify the second laser beam LB2 and output a laser beam LB. The laser beam LB may have the same wavelength as the second laser beam LB2.

The first laser beam LB1, the second laser beam LB2, and the laser beam LB may have the same intensity-time profile by adjusting an amplification ratio. For example, the first laser beam LB1, the second laser beam LB2, and the laser beam LB may have substantially the same pulse width, kurtosis, and skewness. However, the implementation is not limited thereto, and any one of the first and second laser beams LB1 and LB2 may also have different pulse width, kurtosis, and skewness from the laser beam LB.

The first pump laser diode included in the pre-amplifier 223 may generate a first pump laser beam. The second pump laser diode included in the main amplifier 225 may generate a second pump laser beam. The first pump laser beam may be merged into the optical path of the first laser beam LB1 by an optical coupler, and the second pump laser beam may be merged into the optical path of the second laser beam LB2 by the optical coupler. The first and second pump laser diodes may be driven by radio frequency (RF) power.

In some implementations, the first and second pump laser diodes may have a different wavelength from the first laser beam LB1. In some implementations, the first and second pump laser diodes may have less wavelengths from the first laser beam LB1. In some implementations, the first and second pump laser diodes may have wavelengths of higher absorption rate with respect to the optical fiber than the laser beam LB. As the first pump laser beam is absorbed by the optical fiber, the first laser beam LB1 may be amplified and the second laser beam LB2 may be output. As the second pump laser beam is absorbed by the optical fiber, the second laser beam LB1 may be amplified and the laser beam LB may be output. However, the implementation is not limited thereto, and the first and second pump laser beams may also have the same wavelength as the first laser beam LB1.

In some implementations, an isolator may be provided between the master oscillator 221 and the pre-amplifier 223 and between the pre-amplifier 223 and the main amplifier 225. The isolator may also be referred to as an optical diode, may include an optical component that allows a beam to be transmitted in only one direction. The isolator may prevent reverse propagation of the first laser beam LB1 and the second laser beam LB2.

In some implementations, according to intensity of the laser beam LB to be output finally by the laser device 220, an additional pre-amplifier may be further provided between the pre-amplifier 223 and the main amplifier 225. For example, the laser device 220 may also include two or more pre-amplifiers. The isolator and a collimator may be provided at an output terminal from which the laser beam LB is output by the laser device 220.

In some implementations, the intensity-time profile (hereinafter, time profile) of a single pulse included in the first laser beam LB1, the second laser beam LB2, and the laser beam LB (hereinafter, simply, single pulse) may have a Gaussian distribution. In some implementations, the time profile of the single pulse may have a distribution that is different from the Gaussian distribution. In some implementations, the time profile of the single pulse may have a distribution that is different from Lorentzian distribution.

In some implementations, a full width at half maximum (FWHM) may be in a range of about 1 ps to about 1 μS. In some implementations, the FWHM may be equal to or less than about 500 ns.

In some implementations, the time profile of the single pulse may be symmetrical with respect to the center of the single pulse. In this case, the center of the single pulse may mean the middle point between the start point and the end point of the single pulse. In some implementations, the time profile of the single pulse may be asymmetrical with respect to the center of the single pulse. For example, the time interval from a start point SP of the single pulse to a peak point PP of the intensity of the single pulse may be less than the time interval from the PP of the intensity of the single pulse to an end point EP of the intensity of the single pulse. Alternatively, for example, the time interval from the SP of the single pulse to the PP of the intensity of the single pulse may be greater than the time interval from the PP of the intensity of the single pulse to the EP of the intensity of the single pulse.

In some implementations, the rise time may be greater than or equal to about 1% and less than or equal to about 50% of the FWHM of the single pulse. In this case, the rise time may mean the time taken by the intensity of the single pulse to increase from about 10% of the PP to about 90% of the PP.

In some implementations, peak power of the single pulse included in the laser beam LB may be in a range of about 1 W to about 1 kW. In some implementations, average power of the single pulse may be in a range of about 1 W to about 60 W.

The laser device 220 may have a generally uniform time interval, and may repeatedly output the laser beam LB. In some implementations, the laser device 220 may repeatedly output the laser beam LB at the time interval of equal to or greater than several microseconds. For example, the laser device 220 may repeatedly output the laser beam LB at the time interval of about 10 μs to about 30 μs.

The laser beam LB output by the laser device 220 may be transferred to the focusing lens optics 240 via the beam transfer optical system 230. The beam transfer optical system 230 may include a free space optical system, but is not limited thereto. The beam transfer optical system 230 may include various optical components, such as a polarizer, a lens, a reflector, a prism, and a splitter.

The focusing lens optics 240 may focus the laser beam LB at a location set inside the wafer W. For example, the focusing lens optics 240 may focus the first laser beam L1 and the second laser beam L2 in FIG. 7 at locations set inside the wafer W (for example, the first focus location F1 and the second focus location F2). The focusing lens optics 240 may include a single lens, or a plurality of lenses. The wafer support 260 may support the wafer W while the wafer W is processed.

A controller 250 may generate a signal for controlling the laser device 220. The controller 250 may generate a signal for controlling parameters of the laser beam LB generated by the laser device 220. According to some implementations, the controller 250 may control a pulse width pw, a diameter, and power of the laser beam LB generated by the laser device 220.

In this case, the controller 250 may be implemented as hardware, firmware, software, or an arbitrary combination thereof. For example, the controller 250 may include a computing device, such as a workstation computer, a desktop computer, a laptop computer, and a tablet computer. The controller 250 may also include a simple controller, a microprocessor, a complex processor, such as a CPU, and a GPU, a processor including software, dedicated hardware, or firmware. The controller 250 may be implemented as an application-specific hardware, such as a DSP, a field programmable gate array (FPGA), and an ASIC.

According to some implementations, the operation of the controller 250 may be implemented as instructions stored on a machine-readable medium that may be read and executed by one or more processors. In this case, the machine-readable medium may include an arbitrary mechanism for storing and/or transferring information in a form readable by a machine (for example, a computing device). For example, the machine-readable medium may include read-only memory (ROM), RAM, a magnetic disk storage medium, an optical storage medium, a flash memory device, electrical, optical, acoustical, or other different forms of radio signals (for example, a carrier wave, infrared signals, digital signals, or the like), and other arbitrary signals.

Firmware, software, routines, and instructions may be configured to perform the operations described for the controller 250.

As used herein, the term “at least one of” can refer to and encompass any and all possible combinations of one or more of the associated listed terms. For example, the term “at least one of A, B, or C” means that (i) at least one of A, (ii) at least one of B, (iii) at least one of C, (iv) at least one of A and at least one of B, (v) at least one of B and at least one of C, (vi) at least one of A and at least one of C, or (vi) at least one of A, at least one of B and at least one of C are possible, where A, B and C may be singular or plural.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A semiconductor package comprising:
a substrate;
a semiconductor chip mounted on the substrate, the semiconductor chip including a stopper structure;
chip connection bumps between the substrate and the semiconductor chip; and
an underfill material layer surrounding side surfaces of the chip connection bumps,
wherein the stopper structure has a shape protruding from or recessed into a side surface of the semiconductor chip, the shape comprising an inclined surface with respect to a vertical direction.

2. The semiconductor package of claim 1, wherein the inclined surface comprises a first surface extending in a first oblique line direction and a second surface extending in a second oblique line direction that is different from the first oblique line direction.

3. The semiconductor package of claim 2, wherein the first surface is connected to the second surface.

4. The semiconductor package of claim 2, wherein at least one of the first surface or the second surface comprises a plurality of surfaces.

5. The semiconductor package of claim 1, wherein the underfill material layer surrounds at least a portion of side surfaces of the semiconductor chip, and
wherein a vertical level of an uppermost end of the underfill material layer is lower than a vertical level of an uppermost end of the stopper structure.

6. The semiconductor package of claim 1, wherein a vertical level of an uppermost end of the stopper structure is lower than a vertical level of an upper surface of the semiconductor chip, and a vertical level of a lowermost end of the stopper structure is higher than a vertical level of a lower surface of the semiconductor chip.

7. The semiconductor package of claim 1, wherein a horizontal width of the stopper structure is in a range of about 5 μm to about 30 μm.

8. The semiconductor package of claim 1, wherein a vertical width of the stopper structure is in a range of about 80 μm to about 100 μm.

9. The semiconductor package of claim 1, comprising a dam structure surrounding the semiconductor chip and the underfill material layer on the substrate.

10. A method of manufacturing a semiconductor package, the method comprising:
providing a wafer including a plurality of device forming regions and a scribe lane region, the scribe lane region defining the plurality of device forming regions;
forming a plurality of semiconductor devices respectively in the plurality of device forming regions;
forming a plurality of internal breakages on the wafer by irradiating a first laser beam and a second laser beam along the scribe lane region;
forming a stopper structure on a side surface of each of the plurality of semiconductor devices by separating the plurality of semiconductor devices from each other along the plurality of internal breakages; and
packaging each of the separated plurality of semiconductor devices,
wherein the stopper structure has a shape protruding from or recessed into the side surface of each of the plurality of semiconductor devices, the shape comprising an inclined surface with respect to a vertical direction.

11. The method of claim 10, wherein a first focus location of the first laser beam is apart from a second focus location of the second laser beam in the vertical direction.

12. The method of claim 11, wherein the plurality of internal breakages are connected to form a stopper line between the first focus location and the second focus location, and
wherein forming the stopper structure on the side surface of each of the plurality of semiconductor devices comprises separating the plurality of semiconductor devices from each other along the stopper line.

13. The method of claim 11, wherein the first focus location of the first laser beam overlaps the second focus location of the second laser beam in the vertical direction.

14. The method of claim 11, wherein the first focus location of the first laser beam is offset from the second focus location of the second laser beam in a horizontal direction.

15. The method of claim 11, wherein an intensity of the first laser beam is different from an intensity of the second laser beam.

16. The method of claim 10, wherein the inclined surface comprises a first surface extending in a first oblique line direction and a second surface extending in a second oblique line direction that is different from the first oblique line direction.

17. The method of claim 16, wherein the inclined surface comprises:
a plurality of first surfaces including the first surface; and
one or more second surfaces including the second surface,
wherein the plurality of first surfaces and the one or more second surfaces are connected to each other in an alternating fashion.

18. The method of claim 10, wherein packaging each of the plurality of semiconductor devices comprises preparing a substrate, mounting each of the plurality of semiconductor devices on the substrate, and forming an underfill material layer between each of the plurality of semiconductor devices and the substrate.

19. The method of claim 18, wherein a vertical level of an uppermost end of the underfill material layer is lower than a vertical level of an uppermost end of the stopper structure.

20. A semiconductor package comprising:
a substrate;
a semiconductor chip mounted on the substrate, the semiconductor chip including a stopper structure on a side surface of the semiconductor chip;
chip connection bumps between the substrate and the semiconductor chip;
a dam structure surrounding the semiconductor chip on the substrate; and
an underfill material layer surrounding side surfaces of the chip connection bumps,
wherein the stopper structure has a shape protruding toward an outer side of the semiconductor chip or recessed into an inner side of the semiconductor chip, and the shape comprises a first surface extending in a first oblique line direction and a second surface extending in a second oblique line direction that is different from the first oblique line direction, the first oblique line direction being inclined with respect to a vertical direction, and
wherein an edge of the underfill material layer is in contact with the dam structure, and an upper end of the underfill material layer is in contact with the stopper structure.
